(19) United States
(12) Patent Application Publication
(10) Pub. No.: US 2021/0288121 A1
(43) Pub. Date: Sep. 16, 2021

(54) ARRAY SUBSTRATE, MANUFACTURING METHOD THEREOF, AND DISPLAY DEVICE

(71) Applicant: TCL China Star Optoelectronics Technology Co., Ltd., Shezhen, Guangdong (CN)

(72) Inventor: Ying YAN, Shezhen, Guangdong (CN)

(21) Appl. No.: 16/615,475

(22) PCT Filed: Oct. 29, 2019
(86) PCT No.: PCT/CN2019/113962

§ 371 Date: Nov. 21, 2019

(30) Foreign Application Priority Data
Aug. 13, 2019 (CN) 201910743566.6

(51) Int. Cl. H01L 27/32; H01L 51/56

(52) U.S. Cl. CPC H01L 27/3246; H01L 2227/323; H01L 27/3211; H01L 51/56

(57) ABSTRACT

The present invention discloses an array substrate, a manufacturing method thereof, and a display. The array substrate includes a substrate, and a pixel defining layer disposed on the substrate. The pixel defining layer includes an opening and a retaining wall surrounding the opening. The retaining wall corresponds to a non-light-emitting region, and the opening corresponds to a light-emitting region. A groove is disposed on a side of the retaining wall between two neighboring openings away from the substrate. The array substrate, the manufacturing method thereof, and the display device provided by the present invention effectively reduce display defects caused by ink color mixing by generating grooves on retaining walls between neighboring openings in a pixel defining layer.

### FIELD OF INVENTION

The present invention is related to the field of display, and specifically to an array substrate, a manufacturing method thereof, and a display device.

### BACKGROUND OF INVENTION

Active-matrix organic light-emitting diode (AMOLED) is a display technology, wherein “OLED” describes a specific type of thin-film display technology in which organic compounds form an electroluminescent material, while “AM” refers to the technology behind the addressing of pixels. Presently, AMOLED technology is mainly used in smart phones, and the technology continues to develop toward low-power consumption, low cost, and large size.

As shown in FIG. 1, an inkjet printing technology has good application prospect in a preparation of an organic functional layer of an AMOLED display device. The inkjet printing technology directly drops ink dissolving an OLED material into a pre-made pixel defining layer, and forms a desired pattern after solvent is volatilized. The pixel defining layer includes a retaining wall and a plurality of arrayed grooves surrounded by the retaining wall. The grooves are used to restrict the ink, and the ink shrinks and forms a film within a range limited by the grooves after baking and drying.

As resolution of display panels increases, pixels become smaller and smaller, which corresponds to increasingly higher requirement for inkjet printing accuracy, and the accuracy and ink drop volume become more and more difficult to control. In order to produce a required substrate, the accuracy of the inkjet printing requires an accurate optimization of position, droplet size, and number of droplets. If these factors are not adjusted properly, a bridge phenomenon may occur, and the ink of neighboring pixels overflows from the grooves of the pixel defining layers and overlap with each other, causing display failure.

### SUMMARY OF INVENTION

In order to solve the problem above, the present invention provides an array substrate, a manufacturing method thereof, and a display device for solving the bridge phenomenon in the prior art due to inaccuracy in ink dropping position in the inkjet printing technology.

The present invention provides an array substrate including a light-emitting region, a non-light-emitting region surrounding the light-emitting region, a substrate, and a pixel defining layer disposed on the substrate. The pixel defining layer includes an opening and a retaining wall surrounding the opening. The retaining wall corresponds to the non-light-emitting region, and the opening corresponds to the light-emitting region. A groove is disposed on a side of the retaining wall between two neighboring openings away from the substrate.

Further, a shape of the side of the retaining wall away from the substrate is one of a convex curve shape, a convex cone shape, or a convex rhombus shape. The groove is disposed in middle of the side of the retaining wall away from the substrate.

Further, an opening width of the groove ranges from 20 to 50 microns, and an opening depth of the groove ranges from 0.5 to 1 micron.

Further, a pixel layer is disposed in any one of the openings, and the pixel layer includes a red pixel layer, a green pixel layer, and a blue pixel layer.

Further, a material of the pixel defining layer is a hydrophobic and oleophobic material.

The present invention further provides a manufacturing method of an array substrate. The array substrate includes a light-emitting region and a non-light-emitting region surrounding the light-emitting region. The manufacturing method of the array substrate comprises the steps of: providing a substrate; preparing a pixel defining layer by forming the pixel defining layer on the substrate, generating an opening in the pixel defining layer corresponding to the light-emitting region, and the opening passing through the pixel defining layer; and generating a groove, wherein a retaining wall is formed between two neighboring openings in the pixel defining layer, and the groove is formed on a side of the retaining wall away from the substrate.

Further, a convex curve surface is formed on the side of the retaining wall away from the substrate.

Further, in the step of preparing the pixel defining layer, the convex curve surface is made with a slit mask.

Further, in the step of generating the groove, the groove disposed on the retaining wall is made with a halftone mask.

The present invention further provides a display device including the array substrate.

An array substrate, a manufacturing method thereof, and a display device provided by the present invention effectively reduce display defects caused by ink color mixing by generating grooves on retaining walls between neighboring openings in a pixel defining layer. Meanwhile, forming the retaining walls into a convex curve structure can let ink dropping on the retaining walls slide down to the openings due to gravity and prevent the ink from color mixing. Because a material of the pixel defining layer is a hydrophobic and oleophobic material, the ink flows to the opening when the ink drops offset to an edge of the convex curve structure. The array substrate is provided with the retaining walls having convex curve surfaces made with an edge-dense middle-sparse slit mask and the grooves disposed on retaining walls made with a halftone mask. In this way, the manufacturing method of the array substrate is simple and convenient for mass production.

### DESCRIPTION OF DRAWINGS

In order to describe technical solutions in the present invention clearly, drawings to be used in the description of embodiments will be described briefly below. Obviously, drawings described below are only for some embodiments of the present invention, and other drawings may be obtained by those skilled in the art based on these drawings without creative efforts.

FIG. 1 is a schematic diagram of a pixel defining layer in the prior art.

FIG. 2 is another schematic diagram of the pixel defining layer in the prior art.

FIG. 3 is a schematic diagram of an array substrate of a first embodiment.

FIG. 4 is a partial schematic diagram of the array substrate of the first embodiment.

FIG. 5 is a schematic diagram of an array substrate of a second embodiment.

FIG. 6 is a schematic diagram of a display device of the second embodiment.

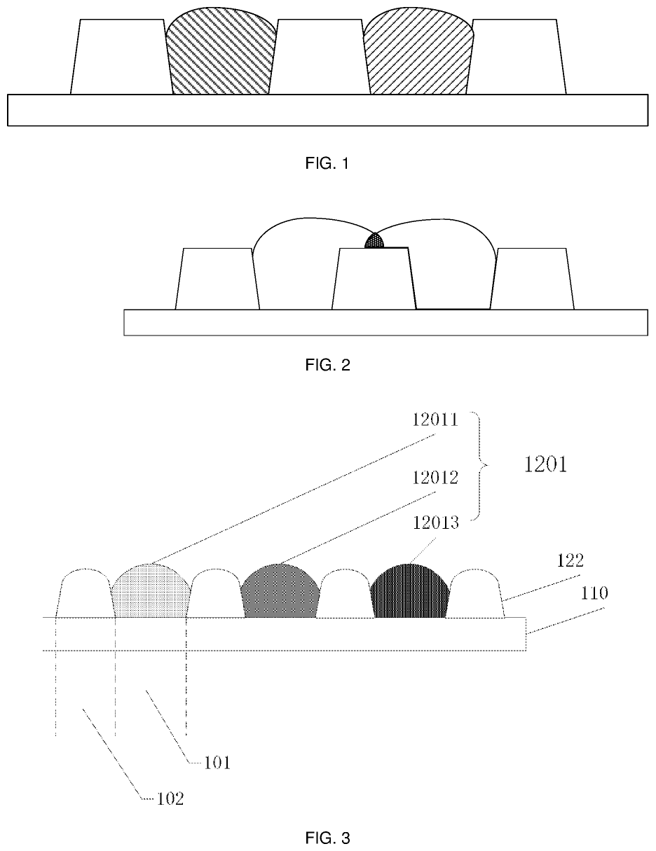

### REFERENCE SIGNS

display device 1; array substrate 10; substrate 110; pixel defining layer 120; light-emitting region 101; non-light-emitting 102; opening 121; retaining wall 122; pixel layer 1201; red pixel layer 12011; green pixel layer 12012; blue pixel layer 12013; and groove 1221.

### DETAILED DESCRIPTION

Examples are described below with reference to the appended drawings, and the drawings illustrate particular embodiments in which the present invention may be practiced. Directional terms mentioned in the present invention, such as upper, lower, front, rear, left, right, top, bottom, etc., only refer to directions in the accompanying drawings. Thus, the adoption of directional terms is used to describe and understand the present invention, but not to limit the present invention.

### First Embodiment

As shown in FIG. 3, in this embodiment, an array substrate 10 of the present invention includes a substrate 110 and a pixel defining layer 120.

The array substrate 10 includes a light-emitting region 101 and a non-light-emitting region 102 surrounding the light-emitting region 101. The light-emitting region 101 is used to provide a display screen.

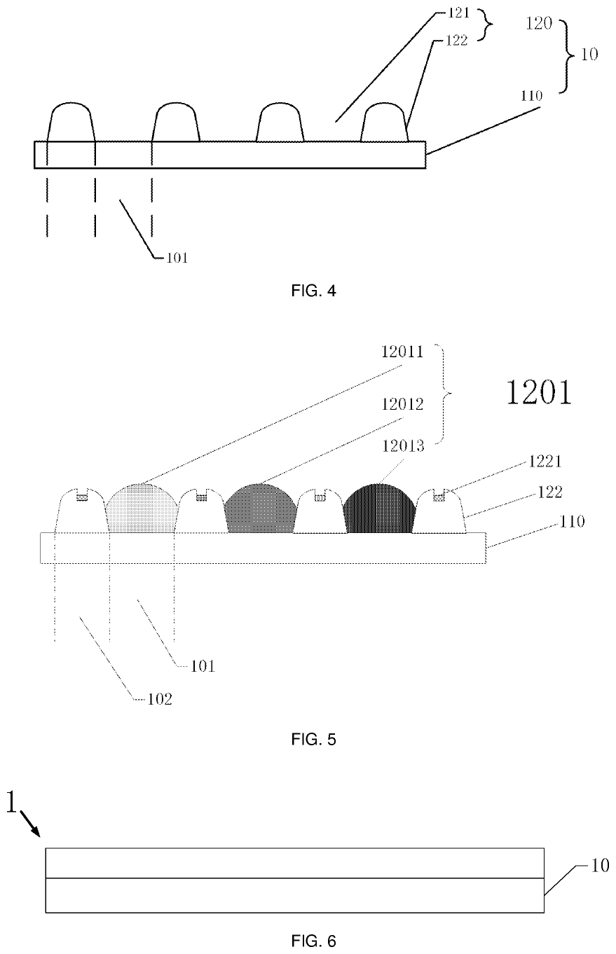

As shown in FIG. 4, the pixel defining layer 120 is disposed on the substrate 110, and a material thereof is a hydrophobic and oleophobic material, such as a fluorine-containing material. In order to receive ink for emitting light, at least one opening 121 is disposed in the pixel defining layer 120 corresponding to the light-emitting region 101. In the pixel defining layer 120, a retaining wall 122 is disposed between neighboring openings 121. The prior art uses an inkjet printing method to drop ink into the opening 121. However, as resolution increases and pixel size decreases, size of the opening 121 become smaller correspondingly so that ink dropping position is inaccurate when dropping the ink, easily leading to a bridge phenomenon. As shown in FIG. 2, ink in neighboring openings 121 overflows from the opening 121, and a portion of overflow spreads to the retaining wall 122 and causes color mixing. In this embodiment, the ink includes red ink, green ink, and blue ink. The ink drops into the opening 121 and forms a pixel layer 1201, wherein the red ink corresponds to a red pixel layer 12011, the green ink corresponds to a green pixel layer 12012, and the blue ink corresponds to a blue pixel layer 12013. As the red ink is offset to an edge of the opening 121 and overflows to the retaining wall during the dropping process, the green ink is offset to the edge of the opening 121 and overflows to the retaining wall neighboring the red ink during the dropping process, and the two inks bridge, forming a new color and causing color mixing. In order to solve the problem, in this embodiment, the retaining wall 122 is formed with a convex surface structure. As shown in FIG. 3, in this embodiment, the convex curve structure on a side of the retaining wall 122 away from the substrate 110 can let ink dropping on the retaining wall 122 slide down to the opening 121 due to gravity and prevent the ink from color mixing.

### Second Embodiment

In this embodiment, an array substrate 10 of the present invention includes a substrate 110 and a pixel defining layer 120.

The array substrate 10 includes a light-emitting region 101 and a non-light-emitting region 102 surrounding the light-emitting region 101. The light-emitting region 101 is used to provide a display screen.

The pixel defining layer 120 is disposed on the substrate 110, and a material thereof is a hydrophobic and oleophobic material, such as a fluorine-containing material. As shown in FIG. 4, in order to receive ink for light-emitting, at least one opening 121 is disposed in the pixel defining layer 120 corresponding to the light-emitting region 101. In the pixel defining layer 120, a retaining wall 122 is disposed between neighboring openings 121. The prior art uses an inkjet printing method to drop ink into the opening 121. However, as resolution increases and pixel size decreases, size of the opening 121 become smaller correspondingly so that ink dropping position is inaccurate when dropping the ink, easily leading to a bridge phenomenon. That is, ink in neighboring openings 121 overflows from the opening 121, and a portion of overflow spreads to the retaining wall 122 and causes color mixing. In this embodiment, the ink includes red ink, green ink, and blue ink. The ink drops into the opening 121 and forms a pixel layer 1201, wherein the red ink corresponds to a red pixel layer 12011, the green ink corresponds to a green pixel layer 12012, and the blue ink corresponds to a blue pixel layer 12013. As the red ink is offset to an edge of the opening 121 and overflows to the retaining wall during the dropping process, the green ink is offset to the edge of the opening 121 and overflows to the retaining wall neighboring the red ink during the dropping process, and the two inks bridge, forming a new color, and causing color mixing.

In order to solve the problem, as shown in FIG. 5, the retaining wall 122 is formed with a convex surface structure. In this embodiment, the convex curve structure on a side of the retaining wall 122 away from the substrate 110 can let ink dropping on the retaining wall 122 slide down to the opening due to gravity and prevent the ink from color mixing. A groove 1221 is disposed on the retaining wall 122. The groove 1221 surrounds the opening 121. A length of the groove 1221 ranges from 40 to 120 microns, equal to a length of the opening 121. An opening width of the groove 1221 ranges from 20 to 50 microns, and an opening depth of the groove 1221 ranges from 0.5 to 1 micron. If the ink dropping position is more offset, the ink falls into the groove 1221 in the middle of the retaining wall, and does not cause the bridge phenomenon. In the meantime, the ink in the groove 1221 does not emit light because there is no light-emitting source in the groove 1221, preventing the ink from color mixing.

In order to better explain the present invention, a manufacturing method of an array substrate in this embodiment includes the steps of:

providing a substrate;

preparing a pixel defining layer by forming the pixel defining layer on the substrate, generating an opening in the pixel defining layer corresponding to the light-emitting region, and the opening passing through the pixel defining layer; and

generating a groove, wherein a retaining wall is formed between two neighboring openings in the pixel defining layer, and the retaining wall is formed with a convex curve surface away from a side of the substrate, and the groove is formed in the retaining wall by using a halftone mask.

In this embodiment, as shown in FIG. 6, a display device 1 of the present invention includes an array substrate 10. All technical features and technical effects of the display device 1 are embodied on the array substrate 10, and other components of the display device 1 will not be described herein again.

The foregoing are only preferred embodiments and are not for use in limiting the disclosure. Any modification, equivalent replacement, or improvement made without departing from the spirit and principles shall be covered by the protection scope.

What is claimed is:

1. An array substrate, comprising:
a light-emitting region;
a non-light-emitting region surrounding the light-emitting region;
a substrate; and
a pixel defining layer disposed on the substrate, the pixel defining layer comprising an opening and a retaining wall surrounding the opening, the retaining wall corresponding to the non-light-emitting region, and the opening corresponding to the light-emitting region;
wherein a groove is disposed on a side of the retaining wall between two neighboring openings away from the substrate.

2. The array substrate as claimed in claim 1, wherein a shape of the side of the retaining wall away from the substrate is one of a convex curve shape, a convex cone shape, or a convex rhombus shape; and
the groove is disposed in middle of the side of the retaining wall away from the substrate.

3. The array substrate as claimed in claim 1, wherein an opening width of the groove ranges from 20 to 50 microns, and an opening depth of the groove ranges from 0.5 to 1 micron.

4. The array substrate as claimed in claim 1, wherein a pixel layer is disposed in any one of the openings, and the pixel layer comprises a red pixel layer, a green pixel layer, and a blue pixel layer.

5. The array substrate as claimed in claim 1, wherein a material of the pixel defining layer is a hydrophobic and oleophobic material.

6. A manufacturing method of an array substrate, wherein the array substrate comprises a light-emitting region and a non-light-emitting region surrounding the light-emitting region, and the manufacturing method of the array substrate comprises the steps of:
providing a substrate;
preparing a pixel defining layer by forming the pixel defining layer on the substrate, generating an opening in the pixel defining layer corresponding to the light-emitting region, and the opening passing through the pixel defining layer; and
generating a groove, wherein a retaining wall is formed between two neighboring openings in the pixel defining layer, and the groove is formed on a side of the retaining wall away from the substrate.

7. The manufacturing method of the array substrate as claimed in claim 6, wherein a convex curve surface is formed on the side of the retaining wall away from the substrate.

8. The manufacturing method of the array substrate as claimed in claim 7, wherein in the step of preparing the pixel defining layer, the convex curve surface is made with a slit mask.

9. The manufacturing method of the array substrate as claimed in claim 6, wherein in the step of generating the groove, the groove disposed on the retaining wall is made with a halftone mask.

10. A display device, wherein the display device comprises the array substrate as claimed in claim 1.
